(19) United States
(12) Patent Application Publication
(10) Pub. No.: US 2018/0337307 A1
(43) Pub. Date: Nov. 22, 2018

(54) NITRIDE SEMICONDUCTOR LIGHT EMITTING DEVICE INCLUDING BUFFER LAYER AND METHOD OF FORMING THE SAME

(71) Applicant: Samsung Electronics Co., Ltd., Suwon-si (KR)

(72) Inventors: Jung Taek HAN, Seoul (KR); Jong Sun MAENG, Suwon-si (KR); Jeen Seok CHO, Hwaseong-si (KR); Sun Woon KIM, Seoul (KR); Yong Hee JEONG, Yongin-si (KR)

(21) Appl. No.: 15/842,000

(22) Filed: Dec. 14, 2017

(30) Foreign Application Priority Data
May 18, 2017 (KR) 10-2017-0061585

(51) Int. Cl. H01L 33/32; H01L 33/12

(52) U.S. Cl. CPC H01L 33/325; B82Y 20/00; H01L 33/12

(57) ABSTRACT

A semiconductor light emitting device includes a Group-III nitride semiconductor layer on a buffer layer. The buffer layer includes a first layer, a second layer, and a third layer in that order. Each of the first layer, the second layer, and the third layer includes a composition which includes aluminum (Al), nitrogen (N), and oxygen (O). A minimum or average value of an oxygen concentration (atoms/cm³) of each of the first layer and the third layer is greater than an oxygen concentration (atoms/cm³) of the second layer.

### CROSS-REFERENCE TO RELATED APPLICATION

Korean Patent Application No. 10-2017-0061585, filed on May 18, 2017, and entitled, “Nitride Semiconductor Light Emitting Device Including Buffer Layer And Method Of Forming The Same,” is incorporated by reference herein in its entirety.

### BACKGROUND

### 1. Field

One or more embodiments described herein relate to a nitride semiconductor light emitting device including a buffer layer and a method for forming the same.

### 2. Description of the Related Art

One type of semiconductor light emitting device emits light based on a recombination of electrons and holes in a light emitting layer. Such a device is used as a light source for lighting apparatuses and flat panel displays.

A semiconductor light emitting device may be formed from a material which includes a Group-III nitride. The Group-III nitride may be grown on a substrate to form a high quality single crystalline layer. However, when the nitride is grown, dislocation density may be high as a result of a lattice constant mismatch between the substrate and the Group-III nitride layer. As a result, cracks, warpage, and/or other defects may occur due to different thermal expansion coefficients of the layers.

### SUMMARY

In accordance with one or more embodiments, a semiconductor light emitting device includes a substrate; a buffer layer on the substrate and including a first layer, a second layer, and a third layer in order; and a Group-III nitride semiconductor layer on the buffer layer, wherein each of the first layer, the second layer, and the third layer includes a composition which includes aluminum (Al), nitrogen (N), and oxygen (O) and wherein a minimum value of an oxygen concentration (atoms/cm³) of each of the first layer and the third layer is greater than an oxygen concentration (atoms/cm³) of the second layer.

In accordance with one or more other embodiments, a semiconductor light emitting device includes a substrate; a buffer layer on the substrate and including a first layer, a second layer, and a third layer in order; and a Group-III nitride semiconductor layer on the buffer layer, wherein each of the first layer, the second layer, and the third layer includes a composition which includes aluminum (Al), nitrogen (N), and oxygen (O) and wherein an average value of an oxygen concentration (atoms/cm³) of each of the first layer and the third layer is greater than an oxygen concentration (atoms/cm³) of the second layer.

In accordance with one or more other embodiments, a method for forming a semiconductor light emitting device includes forming a first buffer layer on a substrate using a first physical vapor deposition (PVD) method, the first PVD method using an aluminum target and a gas containing nitrogen and a gas containing oxygen: forming a second buffer layer on the first buffer layer using a second PVD method, the second PVD method using an aluminum target and a gas containing nitrogen; forming a third buffer layer on the second buffer layer using a third PVD method, the third PVD method using an aluminum target is used and a gas containing nitrogen and a gas containing oxygen; and forming a Group-III nitride semiconductor layer on the third buffer layer.

### BRIEF DESCRIPTION OF THE DRAWINGS

Features will become apparent to those of skill in the art by describing in detail exemplary embodiments with reference to the attached drawings in which:

FIGS. 1 to 4 illustrate embodiments of a buffer layer of a semiconductor light emitting device;

FIG. 5 illustrates an embodiment of a physical vapor deposition apparatus;

FIGS. 6 to 8 illustrate embodiments of semiconductor light emitting device;

FIG. 9 illustrates an embodiment of a lighting apparatus; and

FIG. 10 illustrates an embodiment of a liquid crystal display.

### DETAILED DESCRIPTION

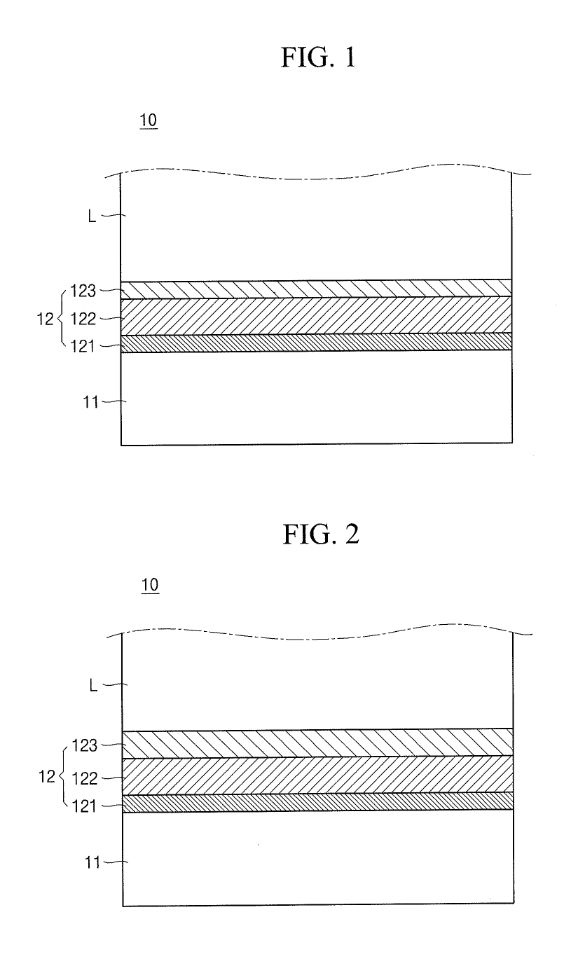

FIGS. 1 to 4 are cross-sectional views illustrating embodiments of a buffer layer which may be used, for example, in a semiconductor light emitting device.

Referring to FIG. 1, a semiconductor light emitting device 10 includes a buffer layer 12 on a substrate 11 and a semiconductor stacked-layer structure L on the buffer layer 12. The semiconductor stacked-layer structure L may be connected to an electrode.

The substrate 11 may include, for example, sapphire, SiC, Si, MgAl₂O₄, MgO, LiAlO₂, LiGaO₂, or GaN. In one embodiment, the buffer layer 12 may be formed on a sapphire substrate as the substrate 11 to reduce lattice mismatch, improve crystalline properties, and allow for formation of a high quality semiconductor stacked-layer structure L.

The buffer layer 12 includes a first layer 121, a second layer 122, and a third layer 123. The first layer 121 is on the substrate 11, the second layer 122 is on the first layer 121, and the third layer 123 is on the second layer 122. The semiconductor stacked-layer structure L may be on the third layer 123.

Each of the first layer 121, the second layer 122, and the third layer 123 may include, for example, a composition containing aluminum (Al), nitride (N), and oxygen (O). A minimum value of an oxygen concentration (atoms/cm³) of the first layer 121 may be greater than that of the second layer 122. A minimum value of an oxygen concentration (atoms/cm³) of the third layer 123 may be greater than that of the second layer 122.

In one embodiment, the oxygen concentration (atoms/cm³) of the second layer 122 may decrease gradually from an interface between the first layer 121 and the second layer 122 to a central portion of the second layer 122. In one embodiment, the oxygen concentration (atoms/cm³) of the buffer layer 12 may have the lowest value in the second layer 122 and the highest value in the third layer 123.

In one embodiment, an average value of the oxygen concentration (atoms/cm³) of each of the first layer 121 and the third layer 123 may be greater than that of the second layer 122 in the buffer layer 12.

Since an oxygen concentration profile of the first layer 121, the second layer 122, and the third layer 123 in the buffer layer 12 is provided as described above, a high quality single crystalline semiconductor layer may be grown on the substrate, with the buffer layer 12 between the substrate 11 and the single crystalline semiconductor layer.

Since the minimum and/or average value of the oxygen concentration (atoms/cm³) of the first layer 121, which is on an interface between the substrate 11 and the buffer layer 12, is greater than that of the second layer 122, an improvement in lattice mismatch between the substrate 11 and the buffer layer 12 may be achieved.

Since the minimum and/or average value of an oxygen concentration (atoms/cm³) of the third layer 123, which is on an interface between the semiconductor stacked-layer structure L and the buffer layer 12, is greater than that of the second layer 122, wetting properties may be improved. Thus, growth of a subsequent semiconductor layer into a two-dimensional epitaxial thin film may be facilitated. For example, since the presence of oxygen in the third layer 123 controls polarity, the third layer 123 containing aluminum is changed into a surface with polarity. Thus, generation of an inversion domain boundary may be reduced and a factor by which the subsequent semiconductor layer is grown into a polycrystalline layer may be suppressed.

In one embodiment, the minimum and/or average value of the oxygen concentration (atoms/cm³) of the third layer 123 may be greater than that of the second layer 122, and also may be greater than that of the first layer 121.

Since the minimum and/or average value of the oxygen concentration (atoms/cm³) of the third layer 123 is greater than that of the first layer, a factor by which the semiconductor layer subsequent to the third layer 123 is grown into a polycrystalline layer may be suppressed. Also, an improvement for facilitating epitaxial growth may be achieved.

The oxygen concentration of each of the first layer 121 and the third layer 123 may be in the range of 1E¹⁹ to 1E²⁴ atoms/cm³. The oxygen concentration of the second layer 122 may be in the range of 1E¹⁸ to 1E²³ atoms/cm³.

The oxygen concentrations (atoms/cm³) of the first layer 121, the second layer 122, and the third layer 123 in the buffer layer 12 may be measured through a secondary ion mass spectrometry (SIMS) analysis.

The thickness of each of the first layer 121 and the third layer 123 may be in a predetermined range, e.g., the range of 0.3 to 3 nm. In one embodiment, the thickness of each of the first layer 121 and the third layer 123 may be in the range of 0.5 to 2 nm. The thicknesses of the first layer 121 and the third layer 123 may be the same or different from each other. When the thickness of each of the first layer 121 and the third layer 123 is greater than 3 nm, in some cases the first layer 121 and the third layer 123 may not sufficiently serve as buffer layers suitable for solving the problem of lattice constant mismatch between the substrate 11 and the semiconductor stacked-layer structure L. When the thickness of each of the first layer 121 and the third layer 123 is less than 0.3 nm, in some cases epitaxial growth of the subsequent semiconductor layer may not be reliably attained and the probability that a subsequent semiconductor layer is grown into a polycrystalline layer is increased.

The total thickness of the buffer layer 12 may be in a predetermined range, e.g., the range of 5 to 200 nm. In one embodiment, the total thickness of the buffer layer 12 may be in the range of 10 to 100 nm. When the thickness of the buffer layer 12 is greater than 200 nm, a function of the buffer layer 12 may be degraded. When the thickness of the buffer layer 12 is less than 5 nm, epitaxial growth of the subsequent semiconductor layer may not be reliably achieved.

The thickness of the second layer 122 may be greater than the thickness of each of the first layer 121 and the third layer 123. The thickness of the second layer 122 may have a value obtained by subtracting the thicknesses of the first layer 121 and the third layer 123 from the total thickness of the buffer layer 12. In one embodiment, the thickness of the second layer 122 may be in the range of 4 to 150 nm. In one embodiment, the thickness of the second layer 122 may be in the range of 6 to 50 nm.

Referring to FIG. 2, the thickness of the third layer 123 may be greater than the thickness of the first layer 121 in the buffer layer 12. The thickness of the second layer 122 may be greater than that of the third layer 123. In one embodiment, the thickness of the third layer 123 may be 1.2 to 3 times that of the first layer 121. In one embodiment, the thickness of the second layer 122 may be 5 to 50 times that of the third layer 123.

Since thicknesses of the first layer 121, the second layer 122, and the third layer 123 in the buffer layer 12 are provided as described above, a factor by which the subsequent semiconductor layer is grown into a polycrystalline layer is suppressed. Thus, an effect of facilitating epitaxial growth may be improved.

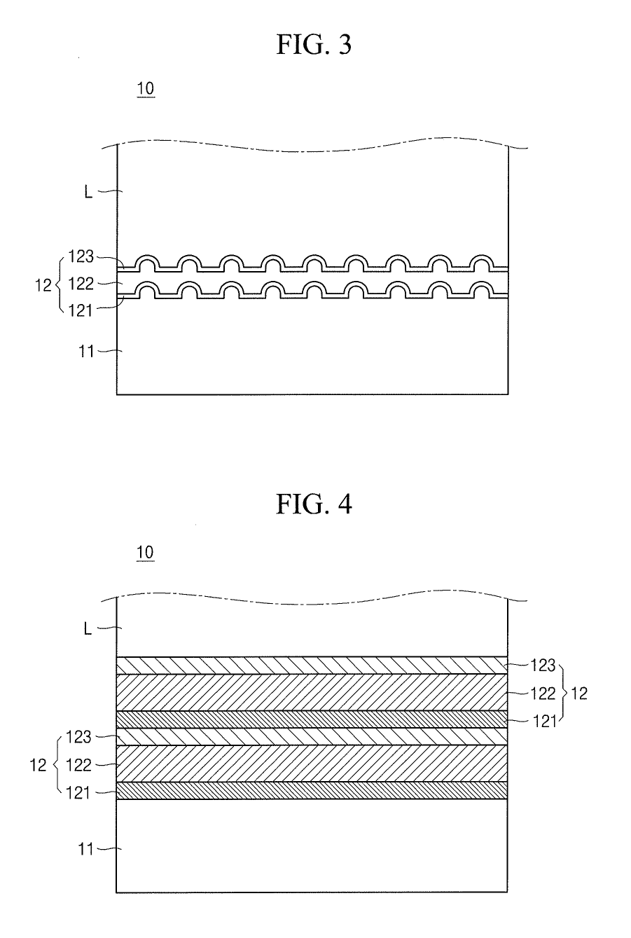

Referring to FIG. 3, a substrate having irregularities is used as the substrate 11, and the buffer layer 12 having an irregular shape may be formed on the substrate 11. The irregular shape of the buffer layer 12 may allow epitaxial lateral overgrowth (FLOG) of the subsequent semiconductor layer to be attained on the buffer layer 12, and crystalline properties may be improved. In one embodiment, growth of the semiconductor layer is suppressed at protrusion areas in an irregular structure of the buffer layer 12, and growth of the semiconductor layer may be induced in a C-axis direction at a lower end plane (C-plane) in the irregular structure.

In the buffer layer 12 illustrated in FIG. 3, the irregularities have a semicircular shape. However, the irregularities may have different shapes (e.g., pillar shapes, mountain shapes, or other shapes) in other embodiments.

Referring to FIG. 4, the buffer layer 12 may be repeatedly formed and stacked on the substrate 11. Each buffer layer 12 includes the first layer 121, the second layer 122, and the third layer 123 in order from the substrate 11. Each of the first layer 121, the second layer 122, and the third layer 123 in the buffer layer 12 may be formed, for example, of a composition containing aluminum (Al), nitrogen (N), and oxygen (O), provided that the minimum value of the oxygen concentration (atoms/cm³) of each of the first layer 121 and the third layer 123 is greater than that of the second layer 122, and/or the average value of the oxygen concentration (atoms/cm³) of each of the first layer 121 and the third layer 123 is greater than that of the second layer 122.

In the semiconductor light emitting device 10 illustrated in FIG. 4, two buffer layers 12,12 are repeatedly stacked, but a plurality of three or more buffer layers may be repeatedly stacked in another embodiment.

By including the plurality of buffer layers, an improvement in preventing a dislocation defect from diffusing upward may be achieved, and a high quality single crystalline semiconductor layer may be grown on the buffer layer 12.

The buffer layer 12 illustrated in FIGS. 1 to 4 may be formed, for example, using a physical vapor deposition (PVD) method. This method may be simpler and increase productivity compared to other methods. Also, a high reproducibility of the oxygen concentration profile of the first layer 121, the second layer 122, and the third layer 123 in buffer layer 12 may be easily achieved by using a PVD method.

When the buffer layer 12 is formed using a PVD method, aluminum (Al) may be used as a target and a gas containing nitrogen and/or a gas containing oxygen may be supplied. As a result, a layer including a composition containing aluminum (Al), nitrogen (N), and oxygen (O) may be formed.

In one embodiment, aluminum nitride (AlN) may be used as a target and a gas containing oxygen may be supplied to a surface of the AlN. As a result, a layer including a composition containing aluminum (Al), nitrogen (N), and oxygen (O) may also be formed.

In one embodiment, an AlN layer may be formed using a PVD method, which may be followed by a thermal oxidation process. As a result, a layer may be formed which includes a composition containing aluminum (Al), nitrogen (N), and oxygen (O).

The buffer layer 12 may be formed using a sputtering method, where aluminum (Al) is used as a target and a gas containing nitrogen and/or gas containing oxygen is supplied as a source gas. This may allow for efficient control of the oxygen concentration profiles of the first layer 121, the second layer 122, and the third layer 123, and may allow for easy manufacturing of the buffer layer 12 including the first layer 121, the second layer 122, and the third layer 123 through an in-line process.

When the buffer layer 12 is formed using a sputtering method, the composition and/or ratio of the supplied source gas may be changed in order to form the first layer 121, the second layer 122, and the third layer 123 sequentially. The first layer 121 may be formed by sputtering of an aluminum target with supply of a gas containing nitrogen and a gas containing oxygen. The second layer 122 may be formed by sputtering of the aluminum target with supply of the gas containing nitrogen. The third layer 123 may be formed by sputtering of the aluminum target with supply of the gas containing nitrogen and the gas containing oxygen.

Referring to FIGS. 1 to 4, after the first layer 121, the second layer 122, and the third layer 123 in the buffer layer 12 are sequentially formed using a PVD method, the semiconductor stacked-layer structure L may be formed on the third layer 123 using a metal-organic chemical vapor deposition (MOCVD) method.

The structure of the semiconductor stacked-layer L and the structure of an electrode formed thereon may vary among embodiments. In one embodiment, the semiconductor layer on the third layer 123 may be a Group-III nitride semiconductor layer represented by AlₐIn_{b}Ga_{(1-a-b)}N (0≤a≤1, 0≤b≤1, and 0≤(a+b)≤1). In one embodiment, the Group-III nitride semiconductor layer may be a GaN layer, an AlGaN layer, or an InGaN layer.

The Group-III nitride semiconductor layer on the buffer layer 12 may be formed, for example, by applying a method such as a MOCVD method, a hydride vapor phase epitaxy (HVPE) method, a molecular beam epitaxy (MBE) method, which are methods for growing a Group-III nitride semiconductor. The Group-III nitride semiconductor layer may be formed using a MOCVD method, for example, to provide for improved thickness control and productivity.

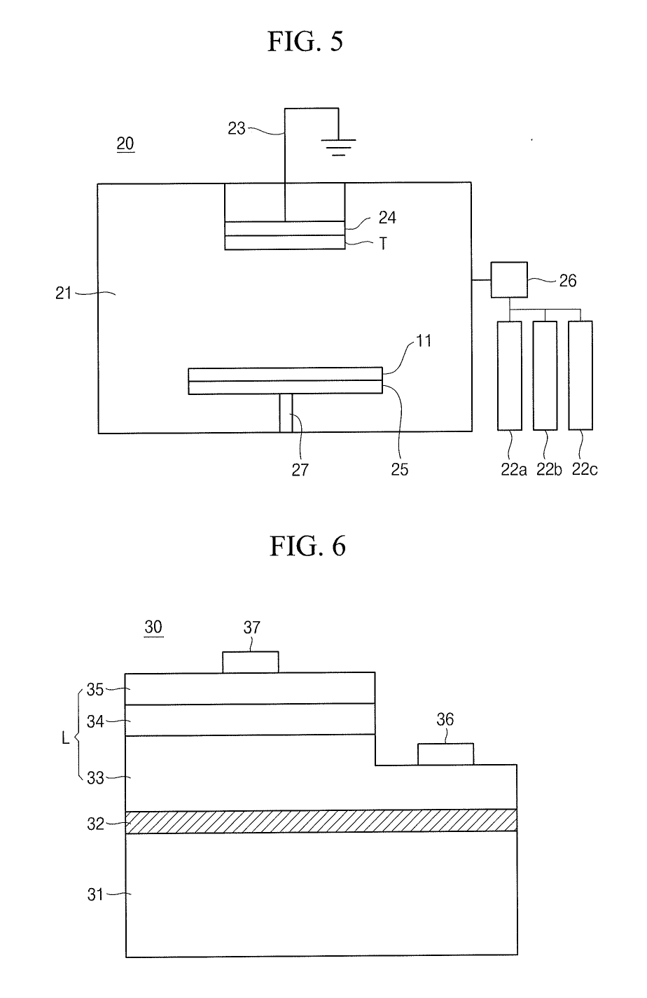

FIG. 5 illustrates a cross-sectional view of an embodiment of a PVD apparatus 20, which, for example, may be used to form the buffer layer of a semiconductor light emitting device such as described above.

Referring to FIG. 5, a PVD apparatus 20 may include a chamber 21, gas supplies 22a, 22b, and 22c, a power supply 23, a target support 24, a substrate support 25, a mass flow controller (MFC) 26, and a substrate lift 27.

In the chamber 21, the target support 24 is installed to face the substrate support 25. The target support 24 and the substrate support 25 are electrically conductive.

The MFC 26 is connected to the gas supplies 22a, 22b, and 22c. The composition and/or ratio of a source gas supplied from each of the gas supplies 22a, 22b, and 22c may be controlled by the MFC 26. A plurality of MFCs may be respectively provided for the plurality of gas supplies 22a, 22b, and 22c. The PVD apparatus 20 may further include a gas discharge portion configured to discharge gas.

Electric power of the power supply 23 may include, for example, direct current (DC) power, pulsed DC power, alternating current (AC) power, or radio frequency (RF) power. A voltage may be applied to the power supply 23 at a target T side in order to allow each electrode of the target and the substrate to have a relative negative voltage or a relative positive voltage respectively. In one embodiment, another power supply may be further installed at a substrate side. In this case, voltages may be applied to both substrate and target sides to set negative and positive electrodes.

In one embodiment, the substrate support 25 is below the target support 24 and the target support 24 is above the substrate support 25. In another embodiment, the substrate support 25 may be above the target support 24 and the target support 24 may be below the substrate support 25.

In one embodiment, an aluminum target T is on the target support 24 installed in the chamber 21 of the PVD apparatus 20, and a substrate 11 is on the substrate support 25. The substrate 11 may be positioned in the chamber by the substrate lift 27. A high purity aluminum with, for example, a purity of 5N5 (99.9995%) may be used as the aluminum target. Next, a source gas is supplied to an inside of the chamber 21 from the gas supplies 22a, 22b, and 22c by control of the MFC 26. A voltage is applied through the power supply 23 connected to the chamber 21. An electrical potential is generated due to the applied voltage, plasma of the source gas is generated in a region between negative and positive electrodes, and thus the buffer layer 12 may be formed on the substrate 11 biased to the positive electrode by sputtering of the target biased to the negative electrode.

Compositions and/or ratios of the supplied source gas may be sequentially controlled by the MFC 26. For example, first, a gas containing nitrogen and a gas containing oxygen may be supplied to the inside of the chamber 21 from the gas supplies 22a, 22b, and 22c to deposit the first layer 121 on the substrate 11. The amount of supplied nitrogen may be in a predetermined range (e.g., the range of 10 to 100 sccm) and the amount of supplied oxygen may be in a predetermined range, e.g., the range of 10 to 30 sccm.

The deposition is performed to form the first layer 121, having a composition containing aluminum (Al), nitrogen (N), and oxygen (O), by supplying the gas containing nitrogen and the gas containing oxygen until the first layer 121 is formed with a predetermined thickness on the substrate 11. The thickness of the first layer 121 may be in a predetermined range, e.g., the range of 0.3 to 3 nm.

When the first layer 121 is deposited to the predetermined thickness, supply of the gas containing oxygen from the gas supplies 22a, 22b, and 22c is stopped by control of the MFC 26, and only the gas containing nitrogen is supplied to the inside of the chamber 21. The amount of supplied nitrogen may be in a predetermined range, e.g., the range of 10 to 100 sccm.

Deposition is performed to form the second layer 122, having a composition containing aluminum (Al), nitrogen (N), and oxygen (O), by supplying the gas containing nitrogen until the second layer 122 is formed with a predetermined thickness on the first layer 121. The thickness of the second layer 122 may be in a predetermined range, e.g., the range of 4 to 150 nm.

When the second layer 122 is deposited to the predetermined thickness, the supply of the gas containing oxygen is restarted from the gas supplies 22a, 22b, and 22c by control of the MFC 26. As a result, the gas containing oxygen and the gas containing nitrogen are supplied to the inside of the chamber 21. The amount of the nitrogen may be in a predetermined range (e.g., the range of 20 to 50 sccm) and the amount of supplied oxygen may be in a predetermined range, e.g., the range of 25 to 40 sccm.

Deposition is performed to form the third layer 123, having a composition containing aluminum (Al), nitrogen (N), and oxygen (O), by supplying the gas containing nitrogen and the gas containing oxygen until the third layer 123 is formed with a predetermined thickness on the second layer 122. The thickness of the third layer 123 may be in a predetermined range, e.g., the range of 0.3 to 3 nm.

When the first layer 121, the second layer 122, and the third layer 123 are formed, at least one of argon (Ar), krypton (Kr), and xenon (Xe) may be supplied as an inert gas within a predetermined range (e.g., the range of 10 to 100 sccm) in addition to the gas containing nitrogen and/or the gas containing oxygen.

The deposition for forming the first layer 121, the second layer 122, and the third layer 123 may be performed in a temperature range of, for example, 200 to 600° C. In one embodiment, the deposition may be performed in the temperature range of 300 to 50° C.

The source gas remaining in the chamber 21 may be discharged through the gas discharge portion after the first layer 121 is formed and before the second layer 122 is formed. Also, the reactive sputtering may be momentarily stopped by turning off the power supply 23 to discharge the gas remaining in the chamber 21. By including a process in which the gas in chamber 21 is discharged and/or power supplying is stopped just before a process of forming a subsequent layer, oxygen concentration of the subsequent layer may be easily controlled.

The buffer layer 12 formed using the forming method according to the above-described embodiment may have a concentration profile in which a minimum value and/or average value of an oxygen concentration (atoms/cm³) of each of the first layer 121 and the third layer 123 is greater than that of the second layer 122.

In the forming method according to the above-described embodiment, the second layer 122 may be formed of a composition containing aluminum (Al), nitrogen (N), and oxygen (O), instead of a composition containing aluminum (Al) and nitrogen (N), by reactive sputtering in the presence of the gas containing oxygen supplied beforehand while the first layer 121 is formed. This composition may be achieved even though deposition of each of the first layer 121 and the third layer 123 is performed by supplying gas containing oxygen and gas containing nitrogen together and even though deposition of the second layer 122 is performed by supplying gas containing nitrogen in a state in which the supply of the gas containing oxygen is stopped.

According to one embodiment, compositions and/or ratios of supplied source gases may be sequentially changed in one PVD apparatus. As a result, the first layer 121, the second layer 122, and the third layer 123 may be formed to include compositions containing aluminum (Al), nitrogen (N), and oxygen (O) in an in-situ manner through an in-line process.

FIGS. 6 to 8 illustrate embodiments of a semiconductor light emitting device 30 which includes a buffer layer 32 on a substrate 31 and a semiconductor stacked-layer structure L on the buffer layer 32. The semiconductor stacked-layer structure L may include a first conductive semiconductor layer 33, an active layer 34, and a second conductive semiconductor layer 35. A first electrode 36 and a second electrode 37 may be respectively formed on and electrically connected to the first conductive semiconductor layer 33 and the second conductive semiconductor layer 35. The buffer layer 32 may include substantially the same structure as the buffer layer 12 illustrated in at least one of FIGS. 1 to 4.

The first conductive semiconductor layer 33 may be formed of a material represented by AlₐIn_{b}Ga_{(1-a-b)}N (0≤a≤1, 0≤b≤1, and 0≤(a+b)≤1). For example, the material may be GaN, AlGaN, or InGaN. The first conductive semiconductor layer 33 may be doped with a first conductive dopant. When the first conductive semiconductor layer 33 is an N-type semiconductor layer, the first conductive dopant may include, for example, at least one of Si, Ge, Sn, Se, and Te as an N-type dopant.

The active layer 34 may be formed to have a structure that includes at least one of a single quantum well (SQW), multi quantum well (MQW), nano rod, quantum-wire, and quantum dot. In one embodiment, the active layer 34 may be formed to have an MQW structure in which quantum well layers and quantum barrier layers are alternately stacked. The quantum well layers and quantum barrier layers may be a pair structure including at least one among InGaN/GaN, InGaN/InGaN, GaN/AlGaN, InAlGaN/GaN, GaAs(InGaAs)/AlGaAs, and GaP(InGaP)/AlGaP. The quantum well layer may be foimed of a material having a bandgap which is lower than that of a material of the quantum barrier layer.

The second conductive semiconductor layer 35 may be formed of a material represented by AlₐIn_{b}Ga_{(1-a-b)}N (0≤a≤1, 0≤b≤1, and 0≤(a+b)≤1). For example, the material may be GaN, AlGaN, or InGaN. The second conductive semiconductor layer 35 may be doped with a second conductive dopant. When the second conductive semiconductor layer 35 is a P-type semiconductor layer, the second conductive dopant may include at least one of Mg, Zn, Ca, Sr, and Ba as a P-type dopant.

The first and second conductive semiconductor layers 33 and 35 may be formed with semiconductor layers respectively doped with N-type and P-type impurities, and conversely may also be formed with semiconductor layers respectively doped with P-type and N-type impurities.

Each of the first and second conductive semiconductor layers 33 and 35 may have a single layer structure or a multilayer structure having different compositions, thicknesses, or other features. For example, each of the first and second conductive semiconductor layers 33 and 35 may further include a carrier injection layer by which injection efficiency of electrons or holes may be improved. In addition. each of the first and second conductive semiconductor layers 33 and 35 may include a superlattice structure in various forms.

The first conductive semiconductor layer 33 may further include a current diffusion layer at a portion adjacent to the active layer 34. The current diffusion layer may have a stacked structure of a plurality of AlₐIn_{b}Ga_{(1-a-b)}N (0≤a≤1, 0≤b≤1, and 0≤(a+b)≤1) layers with different compositions or impurity concentrations. In one embodiment, insulation material layers may be partially formed.

The second conductive semiconductor layer 35 may further include an electron blocking layer at a portion adjacent to the active layer 34. The electron blocking layer may have a stacked structure of a plurality of AlₐIn_{b}Ga_{(1-a-b)}N (0≤a≤1, 0≤b≤1, and 0≤(a+b)≤1) with different compositions, and a bandgap greater than that of the active layer 34 in order to prevent electrons from moving to the second conductive semiconductor layer 35.

The first conductive semiconductor layer 33, the active layer 34, and the second conductive semiconductor layer 35 may be formed using, for example, an MOCVD method. The MOCVD method may include supplying a reactive gas such as an organometallic compound gas (e.g., trimethyl gallium (TMG) or trimethyl aluminum (TMA)) and a gas containing nitrogen (e.g., ammonia (NH₃)) to the inside of a reactive chamber which includes the substrate 31. The substrate may be maintained at a high temperature, for example, in the range of 900 to 1100° C. While a Group-III nitride compound semiconductor is grown on the substrate, an impurity gas may be supplied. As a result, an undoped, an N-type, or a P-type Group-III nitride compound semiconductor may be stacked on the substrate.

In the MOCVD method, hydrogen or nitrogen may be used as a carrier gas, TMG or triethyl gallium (TEG) may be used as a Ga source, TMA or triethyl aluminum (TEA) may be used as an Al source, trimethyl indium (TMI) or triethyl indium (TEI) may be used as an In source, and ammonia (NH₃) or hydrazine (N₂H₄) may be used as an N source. As for dopants, monosilane (SiH₄) or disilane (Si₂H₆) may be used as a Si source, germane gas (GeH₄) and the like may be used as a Ge source for the N-type, and bis-cyclopentadienyl magnesium (Cp₂Mg) or bisethylcyclopentadienyl magnesium ((EtCp)₂Mg) or the like may be used as a Mg source for the P-type.

After the second conductive semiconductor layer 35 and the active layer 34 are partially etched to expose the first conductive semiconductor layer 33, the first electrode 36 may formed on the exposed first conductive semiconductor layer 33. The second electrode 37 may be formed on the second conductive semiconductor layer 35.

The first electrode 36 or the second electrode 37 may have a single layer or multi-layers including at least one of Ag, Ni, Al, Rh, Pd, Ir, Ru, Mg, Zn, Pt, and Au. In one embodiment, the first electrode 36 or the second electrode 37 may have a structure including two or more layers of Ni/Ag, Zn/Ag, Ni/A1, Zn/Al, Pd/Ag, Pd/Al, Ir/Ag, Ir/Au, Pt/Ag, Pt/Al, and Ni/Ag/Pt.

In FIG. 6, the semiconductor light emitting device has a structure in which the first electrode 36 and the second electrode 37 face the same surface as a light emission surface. In another embodiment, the semiconductor light emitting device may have a different structure, e.g., a flip chip structure in which the first electrode 36 and the second electrode 37 are formed in an opposite direction of the light emission surface, a vertical structure in which the first electrode and the second electrode are formed on opposite surfaces, or a vertical and horizontal structure in which several vias are formed to form an electrode structure for improving current diffusion efficiency and heat dissipation efficiency. Positions and connection structures of the first electrode 36 and the second electrode 37 may be different among various embodiments.

The substrate 31 may also be partially or entirely removed or patterned to improve optical or electrical properties of the semiconductor light emitting device during or after a process of manufacturing the semiconductor light emitting device structure. For example, when a sapphire substrate is used, a laser may be irradiated to separate the substrate therefrom, and a silicon or silicon carbide substrate may be removed using polishing, etching, or another method.

When the substrate 31 is removed, another support substrate may be used. Such a support substrate may be bonded using, for example, a reflective metal, or a reflective structure may be inserted into the middle of bonded layers to improve optical efficiency of the semiconductor light emitting device.

When the substrate 31 is patterned, an irregular or inclined surface may be formed on a main surface (a surface or both surfaces) or a side surface of the substrate before or after single crystalline growth. As a result, light emission efficiency and crystalline properties may be improved. The size of the pattern may be, for example, in the range of 5 nm to 500 μm. The structure including a regular or irregular pattern may be selected as long as, for example, the structure improves light emission efficiency. The pattern may have a pillar shape, mountain shape, semicircular shape, or another shape.

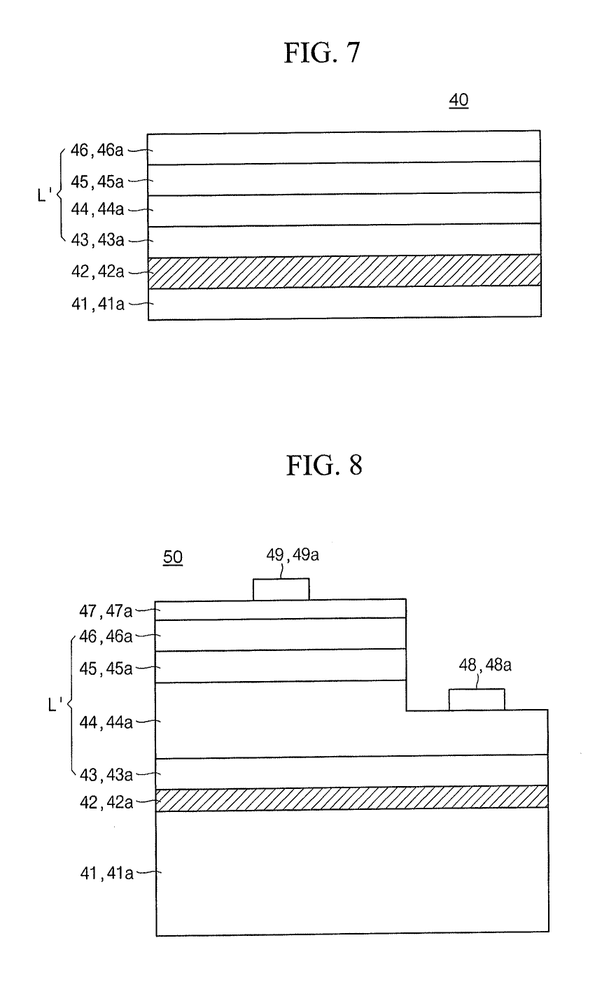

Referring to FIG. 7, a semiconductor light emitting device 40 includes a buffer layer 42 on a substrate 41 and a semiconductor stacked-layer structure L′ on the buffer layer 42. The semiconductor stacked-layer structure L′ may include an undoped semiconductor layer 43 on and in direct contact with the buffer layer 42. A first conductive semiconductor layer 44, an active layer 45, and a second conductive semiconductor layer 46 may be sequentially formed on the undoped semiconductor layer 43. The buffer layer 42 may include substantially the same structure as the buffer layer 12 in at least one of FIGS. 1 to 4. The first conductive semiconductor layer 44, the active layer 45, and the second conductive semiconductor layer 46 may respectively include substantially the same structures as the first conductive semiconductor layer 33, the active layer 34, and the second conductive semiconductor layer 35 illustrated in FIG. 6.

The undoped semiconductor layer 43 may be formed of a material represented by AlₐIn_{b}Ga_{(1-a-b)}N (0≤a≤1, 0≤b≤1, and 0≤(a+b)≤1). The material may be, for example, GaN, AlGaN, and InGaN. The undoped semiconductor layer 43 is not intentionally doped with an impurity such as an N-type dopant and/or a P-type dopant.

In order to form a high quality single crystalline layer, an undoped GaN layer 43a may be formed as the undoped semiconductor layer 43 in direct contact with the buffer layer 42, and an N-type GaN layer 44a doped with an N-type impurity may be formed on the undoped GaN layer 43a. In at least one embodiment, the term “undoped” may mean that an impurity doping process is not additionally performed on a semiconductor layer. However, the semiconductor layer may have impurities such as Si in a predetermined range, e.g., approximately 10¹⁴ to 10¹⁸ atoms/cm³ which is naturally included when a gallium nitride semiconductor is grown using an MOCVD method.

Forming the undoped GaN layer 43a on the buffer layer 42 and forming the N-type GaN layer 44a on the undoped GaN layer 43a may prevent a dislocation defect from diffusing upward. Also, a high quality semiconductor light emitting device may be formed and internal quantum efficiency may be improved.

In the semiconductor light emitting device 40 according to one embodiment illustrated in FIG. 7, a sapphire substrate 41a may be used as the substrate 41, a buffer layer 42a identical to that illustrated in FIG. 1 may be formed on the sapphire substrate 41a, and the undoped GaN layer 43a as the undoped semiconductor layer 43, the N-type GaN layer 44a as the first conductive semiconductor layer 44, an InGaN/GaN layer 45a having a MQW structure as the active layer 45, and a P-type GaN layer 46a as the second conductive semiconductor layer 46 may be sequentially formed on the buffer layer 42a.

The distribution of light emission intensity of the GaN layer of the semiconductor light emitting device 40 according to an embodiment was measured using a photoluminescence (PL) method. The measurement apparatus was a monochromator (Jobin-Yvon GmbH, HR640). A laser (a He-Cd laser having a peak wavelength of 325 nm) having energy greater than a bandgap of the GaN layer was emitted on a plurality of measurement points on the GaN layer having a diameter of 5.08 cm (two inches) to measure an intensity of excited light. The measurement points were distributed over an entire surface of the GaN layer and arranged to have a pitch of 1 mm in a two-dimensional direction parallel to the surface.

As a comparative example, a distribution of a light emission intensity of the GaN layer of a semiconductor light emitting device was also measured using the PL method. The semiconductor light emitting device had the same structure as that of the above embodiment, except that the buffer layer was formed on a sapphire substrate using a PVD method in which an aluminum target was used, and a gas containing nitrogen was used without oxygen injection.

Measurement results were able to confirm that light emission intensity of the GaN layer of the semiconductor light emitting device 40 according to the embodiment was uniformly distributed. It was also confirmed that crystalline properties were improved and the GaN layer was grown as a high quality single crystalline layer. Conversely, the light emission intensity of the GaN layer of the semiconductor light emitting device formed according to the comparative example was not uniform. It was also confirmed that the GaN layer was grown as a polycrystalline layer.

FIG. 8 illustrates an embodiment of a semiconductor light emitting device 50 which includes electrodes. The semiconductor light emitting device 50 may correspond to the semiconductor light emitting device 40 of FIG. 7 equipped with electrodes.

Referring to FIG. 8, an ohmic contact layer 47 is on the second conductive semiconductor layer 46, and a second electrode 49 is on the ohmic contact layer 47. The ohmic contact layer 47 may include an oxide semiconductor layer. In one embodiment, the oxide semiconductor layer may include indium tin oxide (ITO), aluminum zinc oxide (AZO), indium zinc oxide (IZO), ZnO, GZO (ZnO:Ga), In₂O₃, SnO₂, CdO, CdSnO₄, or Ga₂O₃. The ohmic contact layer 47 may be formed using, for example, a sputtering method, an electron beam vapor method, or a vacuum vapor deposition method.

In the semiconductor light emitting device 50, an ITO transparent metal layer 47a may be formed on the P-type GaN layer 46a as the ohmic contact layer 47, and a p-electrode 49a may be formed on the ITO transparent metal layer 47a as the second electrode 49. The P-type GaN layer 46a and the InGaN/GaN layer 45a may be partially etched such that the N-type GaN layer 44a is exposed. An n-electrode 48a may be formed on the exposed N-type GaN layer 44a as the first electrode 48.

In an experiment, a constant current was supplied to the semiconductor light emitting device 50 using a chip prober. The chip prober measured the brightness of light emitted from the semiconductor light emitting device. As a comparative example, a chip prober was used to measure the brightness of light from a semiconductor light emitting device having the same structure as in FIG. 8, except that a GaN buffer layer was formed on a sapphire substrate using an MOCVD method.

The measurement results showed that a center value of light output from the semiconductor light emitting device according to the comparative example was 295 mW, compared to 302 mW which was a center value of light output from the semiconductor light emitting device 50. It was therefore confirmed that light output from the semiconductor light emitting device 50 achieved an improvement of 2% or more compared to the comparative example.

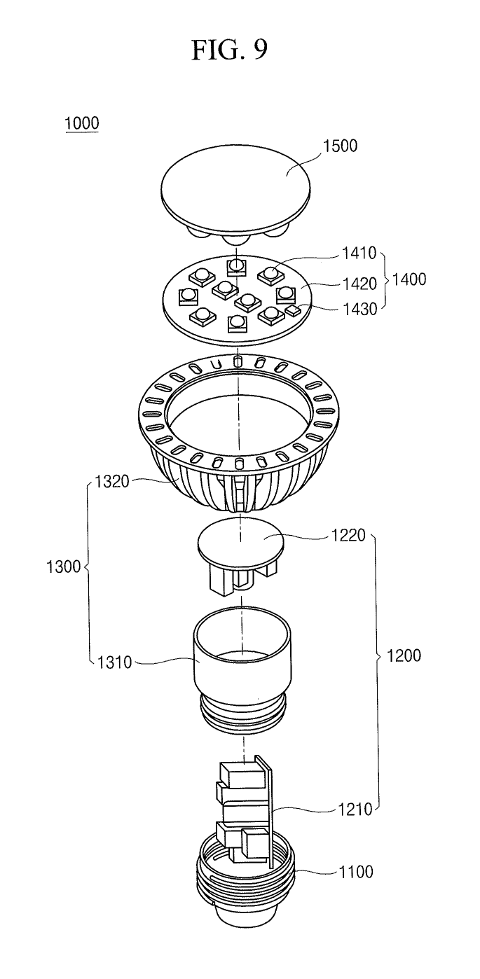

FIG. 9 illustrates an embodiment of a lighting apparatus 1000 which may include any of the embodiments of the semiconductor light emitting device herein.

Referring to FIG. 9, the lighting apparatus 1000 may include a socket 1100, a power supply 1200, a heat sink 1300, a light source module 1400, and an optical portion 1500. In one embodiment, the light source module 1400 may include a light emitting device array, and the power supply 1200 may include a light emitting device driver.

The socket 1100 may be formed to be replaceable with an existing lighting apparatus. Power may be supplied to the lighting apparatus 1000 through the socket 1100. The power supply 1200 may be divided into a first power supply 1210 and a second power supply 1220, and the first power supply 1210 and the second power supply 1220 may be assembled.

The heat sink 1300 may include an internal heat sink 1310 and an external heat sink 1320. The internal heat sink 1310 may be directly connected to the light source module 1400 and/or the power supply 1200, and heat may be accordingly transferred to the external heat sink 1320. The optical portion 1500 may include an internal optical portion and an external optical portion, and may be configured to uniformly distribute light emitted by the light source module 1400.

The light source module 1400 receives power from the power supply 1200 to emit light to the optical portion 1500. The light source module 1400 may include one or more light emitting devices 1410, a circuit board 1420, and a controller 1430. The controller 1430 may store driving information of the light emitting devices 1410. As indicated, the light emitting devices 1410 may include the semiconductor light emitting device according to the various embodiments described herein.

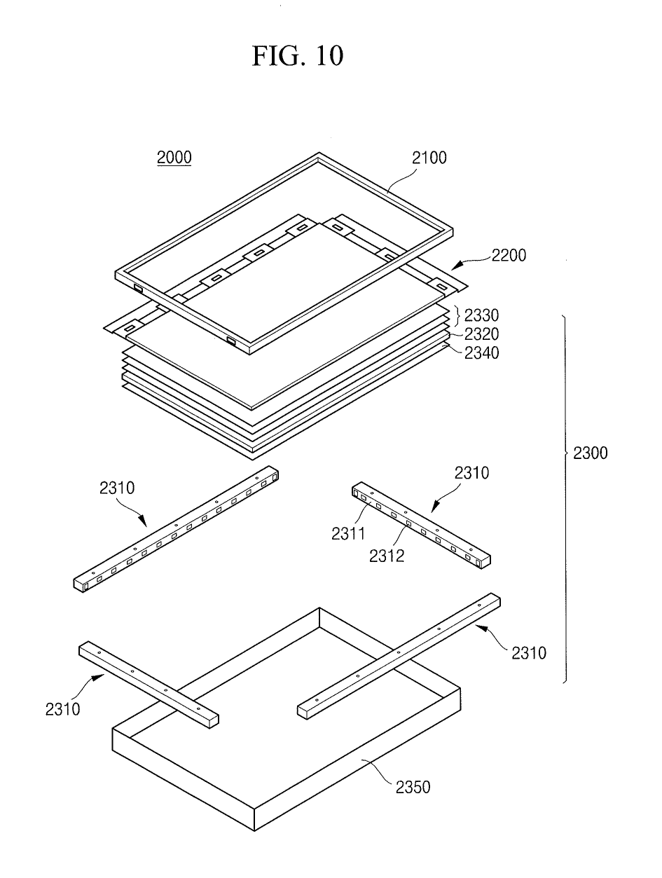

FIG. 10 illustrates an embodiment of a liquid crystal display 2000 which includes one or more semiconductor light emitting devices according to any of the embodiments described herein.

Referring to FIG. 10, the liquid crystal display 2000 may include a front case 2100, a liquid crystal panel 2200, and a backlight unit 2300. The backlight unit 2300 may include light source modules 2310, a light guide panel 2320, an optical sheet 2330, a reflective sheet 2340, and a frame 2350. Each of the light source modules 2310 may include one or more light sources 2312 mounted on a substrate 2311. Each of the light sources 2312 may include a semiconductor light emitting device according to any of the embodiments described herein. The light guide panel 2320, the optical sheet 2330, and the reflective sheet 2340 may be at a side portion of an optical path of the light sources 2312. The backlight unit 2300 illustrated in FIG. 10 may be, for example, an edge type or a direct type.

A semiconductor light emitting device according to the embodiments described herein may be applied, for example, as internal and external light sources for a vehicle. Examples of an internal light source include an interior light, a reading light, various light sources of an instrument panel, and the like, for the vehicle. Examples of an external light source include a headlight, a brake light, a turn signal light, a fog light, a driving light, and the like, for the vehicle. In one embodiment, the semiconductor light emitting device of the embodiments described herein may be applied as a light source for a robot or various other kinds of mechanical equipment.

Other applications of the semiconductor light emitting device according to the embodiments described herein include providing light to expedite plant growth, to stabilize the mood of a person, or to cure or treat a disease using a specific wavelength band. In one embodiment, lighting by an eco-friendly renewable energy power system using a solar cell or wind power may also be implemented in association with low power consumption and a long lifetime of the semiconductor light emitting device.

Also, manufacturing costs may be decreased and optical efficiency may be increased using any of the embodiments of the semiconductor light emitting device described herein, along with their attendant methods. Also, the performance of various kinds of products to which the semiconductor light emitting devices are applied may be significantly improved relative to the cost of those products.

In accordance with one or more of the aforementioned embodiments, a high quality single crystalline layer including a Group-III nitride may be formed on a substrate using a simple and highly reproducible manufacturing process. As a result, a semiconductor light emitting device may be provided with improved light emitting efficiency and light output.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, various changes in form and details may be made without departing from the spirit and scope of the embodiments set forth in the claims.

What is claimed is:

1. A semiconductor light emitting device, comprising:
a substrate;
a buffer layer on the substrate and including a first layer, a second layer, and a third layer in order; and
a Group-III nitride semiconductor layer on the buffer layer, wherein each of the first layer, the second layer, and the third layer includes a composition which includes aluminum (Al), nitrogen (N), and oxygen (O) and wherein a minimum value of an oxygen concentration (atoms/cm³) of each of the first layer and the third layer is greater than a minimum value of an oxygen concentration (atoms/cm³) of the second layer.

2. The semiconductor light emitting device as claimed in claim 1, wherein the oxygen concentration (atoms/cm³) of the second layer decreases from an interface between the first layer and the second layer to a central portion of the second layer.

3. The semiconductor light emitting device as claimed in claim 1, wherein an oxygen concentration (atoms/cm³) of the buffer layer has the lowest value at the second layer and has the highest value at the third layer.

4. The semiconductor light emitting device as claimed in claim 1, wherein the minimum value of the oxygen concentration (atoms/cm³) of the third layer is greater than the minimum value of the oxygen concentration (atoms/cm³) of the first layer.

5. The semiconductor light emitting device as claimed in claim 1, wherein the oxygen concentration of each of the first layer and the third layer included in the buffer layer is in the range of 1E¹⁹ to 1E²⁴ atoms/cm³.

6. The semiconductor light emitting device as claimed in claim 1, wherein the oxygen concentration of the second layer included in the buffer layer is in the range of 1E¹⁸ to 1E²³ atoms/cm³.

7. The semiconductor light emitting device as claimed in claim 1, wherein:
the first layer has a thickness less than a thickness of the second layer, and
a thickness of the third layer is less than the thickness of the second layer.

8. The semiconductor light emitting device as claimed in claim 7, wherein the thickness of each of the first layer and the third layer is in a range of 0.3 to 3 nm.

9. The semiconductor light emitting device as claimed in claim 7, wherein a thickness of the buffer layer is in a range of 5 to 200 nm.

10. The semiconductor light emitting device as claimed in claim 7, wherein the thickness of the third layer is greater than the thickness of the first layer.

11. The semiconductor light emitting device as claimed in claim 1, wherein the buffer layer has an irregular shape.

12. The semiconductor light emitting device as claimed in claim 1, wherein the buffer layer is repeatedly formed and stacked on the substrate.

13. The semiconductor light emitting device as claimed in claim 1, wherein:
the Group-III nitride semiconductor layer includes an undoped GaN layer; and
the undoped GaN layer is in direct contact with the third layer.

14. The semiconductor light emitting device as claimed in claim 1, wherein the substrate includes a sapphire substrate.

15. A semiconductor light emitting device, comprising:
a substrate;
a buffer layer on the substrate and including a first layer, a second layer, and a third layer in order; and
a Group-III nitride semiconductor layer on the buffer layer, wherein each of the first layer, the second layer, and the third layer includes a composition which includes aluminum (Al), nitrogen (N), and oxygen (O) and wherein an average value of an oxygen concentration (atoms/cm³) of each of the first layer and the third layer is greater than an average value of an oxygen concentration (atoms/cm³) of the second layer.

16. The semiconductor light emitting device as claimed in claim 15, wherein the average value of the oxygen concentration (atoms/cm³) of the third layer is greater than the average value of the oxygen concentration (atoms/cm³) of the first layer.

17. A semiconductor light emitting device, comprising:
a substrate;
a buffer layer on the substrate and including a first layer, a second layer, and a third layer in order; and
a Group-III nitride semiconductor layer on the buffer layer, wherein each of the first layer, the second layer, and the third layer includes a composition which includes aluminum (Al), nitrogen (N), and oxygen (O) and wherein an oxygen concentration profile of the first layer, the second layer, and the third layer are different from one another.

18. The semiconductor light emitting device as claimed in claim 17, wherein a minimum value of an oxygen concentration (atoms/cm³) of each of the first layer and the third layer is greater than a minimum value of an oxygen concentration (atoms/cm³) of the second layer.

19. The semiconductor light emitting device as claimed in claim 17, wherein an average value of an oxygen concentration (atoms/cm³) of each of the first layer and the third layer is greater than an average value of an oxygen concentration (atoms/cm³) of the second layer.

20. The semiconductor light emitting device as claimed in claim 17, wherein a thickness of the third layer is greater than a thickness of the first layer.
